(19) United States
(12) Patent Application Publication
(10) Pub. No.: US 2025/0225286 A1
(43) Pub. Date: Jul. 10, 2025

(54) METHOD AND SYSTEM FOR DETERMINING THE PANELIZATION OF A WALL

(71) Applicant: Consulting Engineers, Corp., Reston, VA (US)

(72) Inventor: Maharaj Jalla, Great Falls, VA (US)

(21) Appl. No.: 19/091,799

(22) Filed: Mar. 26, 2025

Related U.S. Application Data
(63) Continuation-in-part of application No. 16/695,406, filed on Nov. 26, 2019.

(51) Int. Cl. G06F 30/13

(52) U.S. Cl. CPC G06F 30/13

(57) ABSTRACT

The present invention is a method comprising receiving architectural drawings of a building; isolating a series of walls from the architectural drawings; calculating a centerline of each segment of the series of the walls; generating a drawing of the centerlines; calculating a thickness of each of the segments of the series of the walls based on the architectural drawings and the centerline drawing; creating a model of the segments of the series of the walls, wherein each segment is comprised of a set of framing members; analyzing the segments of the series of the walls wherein wall panels are formed; manipulating the segments of the series of the walls based on the analyzed wall panels; and generating a model of the each of the wall panels and a model of the building assembly.

### CROSS-REFERENCE TO RELATED APPLICATIONS

This application is a continuation-in-part (and claims the benefit of priority under 35 USC 120) of U.S. provisional application No. 62/291,2688 filed Oct. 9, 2019, U.S. provisional application No. 62/912,690 filed Oct. 9, 2019, and U.S. non-provisional application Ser. No. 16/695,406 filed on Nov. 26, 2019. The disclosure of the prior applications is considered part of (and is incorporated by reference in) the disclosure of this application.

### BACKGROUND

This disclosure relates generally to building construction and to a method, a computer program, or a computer system for determining a panelization layout of a surface using the center line of a surface to develop the layout and features of the surface.

The study of architectural drawing has typically been done manually by the user of the software. To study architectural drawing and to identify different elements in the drawings which are relevant to the software. The user has to manually go through all the features of the architectural drawings and manually convert them to 2D drawings or 3D models. Architectural drawings typically show all the building features which are required for the construction of the building. It shows the different room locations, sizes of the room, and arrangements of different rooms. It also shows the wall finishing material used for the exterior surface and interior surface. It is a tremendous and tedious process to convert this manually to the software format.

However, this process is necessary in any design or detailing software. The task of inputting the walls building per the architectural drawing is necessary to calculate accurate engineering design or drawings reports. Manual method of the inputting of the layout of the building has disadvantages like time-consuming task, leading to an error by incorrect inputs. Even still, many times the walls of a building are preassembled and delivered to the job site. Without extensive calculations and determinations are incredibly difficult to determine the perfect size to make each wall panel to ship and install these panels.

In the process of building construction of cold formed steel and lumber material, the traditional construction method of stick framing is popular where each wall framing member is erected as a stick. To increase the speed of construction, the panelized construction method in which wall is constructed as panel which consist of specific length and height is created and used in building construction.

When an engineering design or detailing software start, the wall as per the Architectural layout is imported in the software. Software has Input for Transportation limit which includes length, height and maximum allowable weight of each wall. Based on the Input from users of software, the Architectural wall convert in panels which are within transportation limit and allowable weight of each wall.

Therefore, it is desired for a program that is able to provide the unique feature of wall panelization in which the wall as per Architectural layout is panelized based on the transportation limit of the construction material. The unique way of wall panelization in Automation software has several advantages over traditional methods. The present invention provides for a system and method to automatically convert the content of the architectural drawings to determine the exact size and measurements of each wall panel to produce a perfect model of the drawings.

### SUMMARY

In a first embodiment, the present invention is a computer method for creating wall panels of a building structure, comprising: receiving, by one or more processors, architectural drawings of a building; isolating, by the one or more processors, a series of walls from the architectural drawings; calculating, by the one or more processors, a centerline of each segment of the series of the walls; generating, by the one or more processors, a drawing of the centerlines; calculating, by the one or more processors, a thickness of each of the segments of the series of the walls based on the architectural drawings and the centerline drawing; creating, by the one or more processors, a model of the segments of the series of the walls, wherein each segment is comprised of a set of framing members; analyzing, by the one or more processors, the segments of the series of the walls wherein wall panels are formed; manipulating, by the one or more processors, the segments of the series of the walls based on the analyzed wall panels; and generating, by the one or more processors, a model of the each of the wall panels and a model of the building assembly.

In a second embodiment, the present invention is a computer program product for creating wall panels of a building structure: the computer program product comprising a computer readable storage medium having program instructions embodied therewith, the program instructions executable by a computing device to cause the computing device to: program instructions to receive architectural drawings of a building, wherein the architectural drawings of the building have multiple floors; program instructions to analyze each of the architectural drawings to identify walls from other components of the architectural drawings and isolating the walls from the other components of the architectural drawings; program instructions to calculate a centerline of each the walls; program instructions to generate a drawing of the centerlines that align with the walls of the architectural drawings; program instructions to calculate a true thickness of each of the walls based on a framing member measurements; program instructions to create a model of the walls, wherein the walls are constructed from the framing member, and wherein the wall is constructed to a building design; program instructions to analyze the walls, and wherein the wall is segmented into a series of wall panels; program instructions to manipulate the segments of the series of wall panels; and program instructions to generate a model of the each of the wall panels and a model of the building assembly.

In a third embodiment, the present invention is a system comprising: a CPU, a computer readable memory and a computer readable storage medium associated with a computing device; program instructions to receive architectural drawings; program instructions to analyze each of the architectural drawings to identify structural features of the architectural drawings and isolating the structural features associated with the walls; program instructions to calculate a centerline of each the walls; program instructions to generate a drawing of the centerlines which aligns with the architectural drawings; program instructions to calculate a true thickness of each of the walls based on a framing member setoff properties; program instructions to create a model of the walls, wherein the walls are constructed from framing members, and wherein the wall is constructed based on a set of building requirements; program instructions to analyze the walls, and wherein the wall is segmented into a series of wall panels; program instructions to manipulate the segments of the series of wall panels and adjust the walls to accommodate these manipulations; and program instructions to generate a model of the each of the wall panels and a model of the building assembly.

### BRIEF DESCRIPTION OF THE DRAWINGS

FIG. 1 depicts a block diagram depicting a computing environment, in accordance with one embodiment of the present invention.

FIG. 2 depicts a block diagram depicting the internal and external components of the server and computing device of FIG. 1, in accordance with one embodiment of the present.

FIG. 3 depicts a cloud computing environment, in accordance with one embodiment of the present invention.

FIG. 4 depicts a flowchart of the operational steps of a method for the construction of wall panels, in accordance with one embodiment of the present invention.

FIG. 5 depicts a user interface showing a floor plan for panelization, in accordance with one embodiment of the present invention.

FIG. 6 depicts a user interface showing a center line construction of the floor plan, in accordance with one embodiment of the present invention.

FIG. 7 depicts a user interface showing a modified view of the floor plan, in accordance with one embodiment of the present invention.

FIG. 8 depicts a user interface showing a center line construction with openings of the floor plan, in accordance with one embodiment of the present invention.

FIG. 9 depicts a user interface showing a 3D model of a portion of the floor plan, in accordance with one embodiment of the present invention.

FIG. 10 depicts wall panels of the 2D model of the wall in elevation, in accordance with one embodiment of the present invention.

FIG. 11 depicts a set of wall panels on a transportation vehicle, in accordance with one embodiment of the present invention.

FIG. 12 depicts a set of wall panels on a transportation vehicle, in accordance with one embodiment of the present invention.

### DETAILED DESCRIPTION

The present invention provides a process of creating a panel layout of interior and exterior walls for buildings for the manufacturing of wall panels for construction. In another embodiment, the present invention provides a method for designing a panel layout for the interior and exterior walls of a building, facilitating the manufacturing of wall panels for construction. The panelization of the walls allows for the walls to be constructed in panels (or sections) that are easily assembled. This creates a more advantageous setup where a large portion of the walls are pre-constructed so there is less work to be done on the job site. The wall panels are calculated based on a set of predetermined restrictions, such as shipping vessel size restrictions. The present invention can analyze the drawings or models provided to create the wall panels. By analyzing architectural drawings, identifying centerlines, and automatically dividing walls into optimized panels based on user-defined constraints such as material type and structural requirements. The present invention optimizes wall panel sizes based on transportation constraints, ensuring that each wall panel adheres to maximum allowable dimensions for efficient shipping and on-site assembly while minimizing material waste.

The present disclosure relates to a method, computer program, and computer system for determining a panelization layout of a surface using a centerline of the surface to develop the layout and features of the surface. This invention automates the conversion of architectural layouts into wall panelization designs by importing the architectural wall layout into a software system. The software utilizes user-defined transportation limits, including length, height, and maximum allowable weight of each wall, to automatically divide the architectural walls into panels that comply with these constraints. The automated panelization process offers significant advantages over traditional stick framing methods, improving construction speed and accuracy by producing precise measurements and optimized wall panel models. This innovative approach streamlines the construction process, minimizes manual input errors, and enhances overall project efficiency.

Typically, with design or detailing software the task of inputting walls into the building model based on the architectural drawing is necessary to calculate accurate engineering design or drawings of the walls. The present invention provides a centerline approach to determining the true dimensions of the wall panels and generate drawings that are true to the framing members without any finishing materials interfering with the dimensions of the panels. These framing drawings are then analyzed to determine the number of panels, the construction of the panels, and the assembly of the panels so that all the panels can be pre-manufactured and assembled and delivered to the job site and adhere to the strict building dimensions and requirements.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

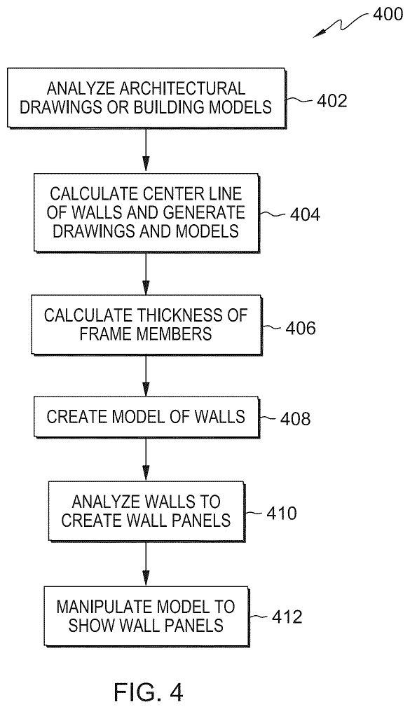

The flowcharts in FIG. 4 illustrate the architecture, functionality, and operation of possible implementations of systems, methods, and computer program products according to various embodiments of the present invention. In this regard, each block in the flowcharts may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the flowchart illustrations, and combinations of blocks in the flowchart illustrations, can be implemented by special purpose hardware-based systems that perform the specified functions or acts or carry out combinations of special purpose hardware and computer instructions.

It is understood in advance that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

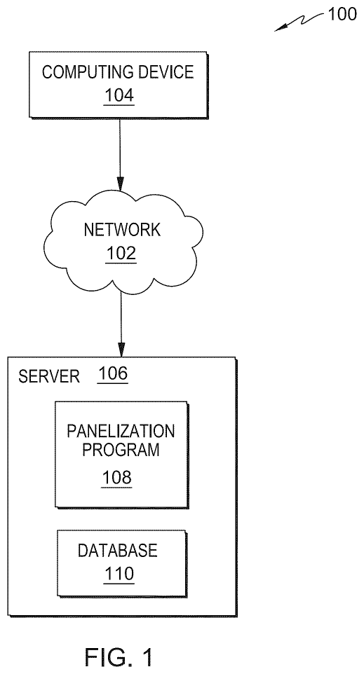

FIG. 1 depicts a block diagram of a computing environment 100 in accordance with one embodiment of the present invention. FIG. 1 provides an illustration of one embodiment and does not imply any limitations regarding the environment in which different embodiments may be implemented.

In the depicted embodiment, computing environment 100 includes network 102, computing device 104, and server 106. Computing environment 100 may include additional servers, computers, or other devices not shown.

Network 102 may be a local area network (LAN), a wide area network (WAN) such as the Internet, any combination thereof, or any combination of connections and protocols that can support communications between computing device 104 and server 106 in accordance with embodiments of the invention. Network 102 may include wired, wireless, or fiber optic connections.

Computing device 104 may be a management server, a web server, or any other electronic device or computing system capable of processing program instructions and receiving and sending data. In other embodiments, computing device 104 may be a laptop computer, tablet computer, netbook computer, personal computer (PC), a desktop computer, or any programmable electronic device capable of communicating with patient computing device 104 via network 102. In other embodiments, computing device 104 may be a server computing system utilizing multiple computers as a server system, such as in a cloud computing environment. In one embodiment, computing device 104 represents a computing system utilizing clustered computers and components to act as a single pool of seamless resources. Computing device 104 may include components, as depicted and described in further detail with respect to FIG. 1.

Server 106 may be a management server, a web server, or any other electronic device or computing system capable of processing program instructions and receiving and sending data. In other embodiments server 106 may be a laptop computer, tablet computer, netbook computer, personal computer (PC), a desktop computer, or any programmable electronic device capable of communicating via network 102. In one embodiment, server 106 may be a server computing system utilizing multiple computers as a server system, such as in a cloud computing environment. In one embodiment, server 106 represents a computing system utilizing clustered computers and components to act as a single pool of seamless resources. In the depicted embodiment Panelization Program 108 and database 110 are located on server 106. Server 106 may include components, as depicted and described in further detail with respect to FIG. 1.

Panelization Program 108 provides the features of analyzing the walls of the building or structure to determine a centerline of the walls to determine the true dimensions of the framing members (without any finishing materials) and then create a set of wall panels to construct the walls. The panelization program 108 is then able to generate a 3D model of each of the panels, the entire wall frame structure (showing the panels in an assembled form), and also create drawings and assembly files for each of the wall panels and the wall frame structure In the depicted embodiment, Panelization Program 108 utilizes network 102 to access the computing device 104 and to communicate with database 110. In one embodiment, Panelization Program 108 resides on computing device 104. In other embodiments, Panelization Program 108 may be located on another server or computing device, provided Panelization Program 108 has access to database 110.

Database 110 may be a repository that may be written to and/or read by Panelization Program 108. Information gathered from computing device 104 and the 1-dimensional, 2-dimensional, and 3-dimensional drawings and models as well as the requirements so that the materials and members are identified as conflicting or non-conflicting. In one embodiment, database 110 is a database management system (DBMS) used to allow the definition, creation, querying, update, and administration of a database(s). In the depicted embodiment, database 110 resides on computing device 104. In other embodiments, database 110 resides on another server, or another computing device, provided that database 110 is accessible to Panelization Program 108.

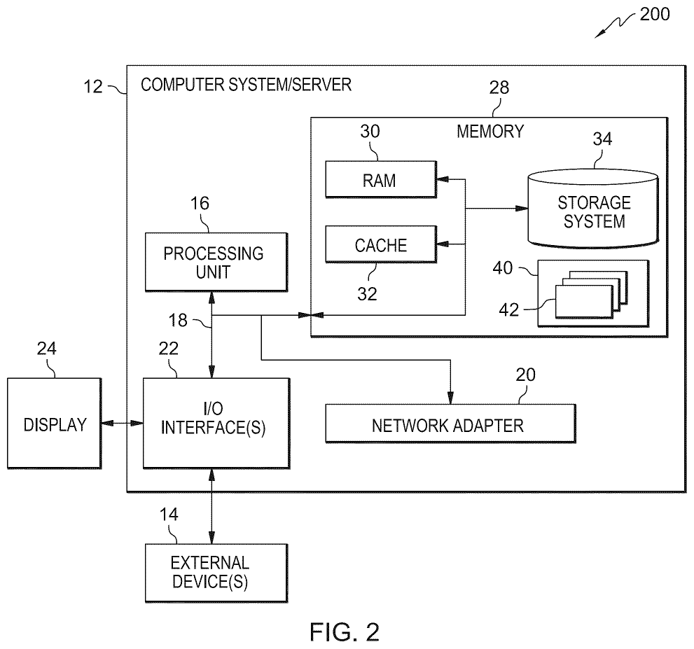

FIG. 2, a schematic of an example of a cloud computing node is shown. Cloud computing node 10 is only one example of a suitable cloud computing node and is not intended to suggest any limitation as to the scope of use or functionality of embodiments of the invention described herein. Regardless, cloud computing node 10 is capable of being implemented and/or performing any of the functionalities set forth hereinabove.

In cloud computing node 10 there is a computer system/server 12, which is operational with numerous other general purposes or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

FIG. 2, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media. System memory 28 can include computer system readable media in the form of volatile memory, such as random-access memory (RAM) 30 and/or cache memory 32. Computer system/server 12 may further include other removable/non-removable, volatile/non-volatile computer system storage media. By way of example only, storage system 34 can be provided for reading from and writing to a nonremovable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples include, but are not limited to microcode, device drivers, redundant processing units, external disk drive arrays, RAID systems, tape drives, and data archival storage systems, etc.

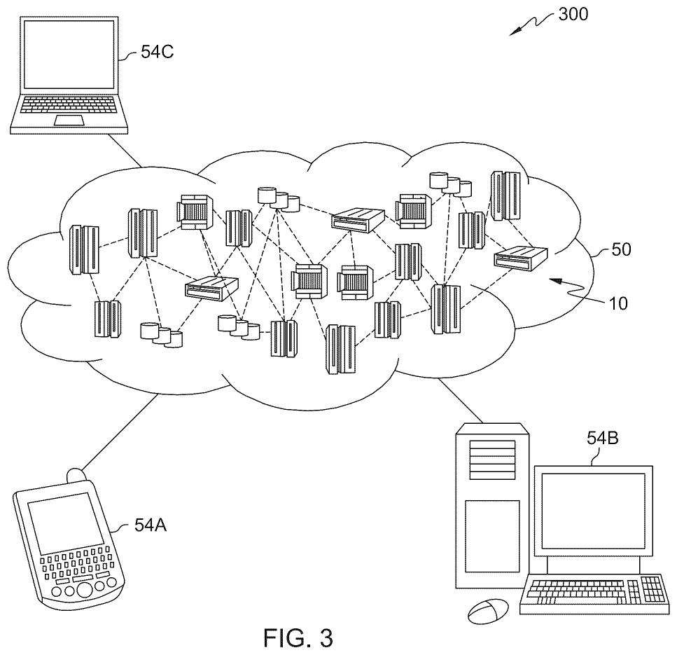

FIG. 3, illustrative cloud computing environment 50 is depicted. As shown, cloud computing environment 50 comprises one or more cloud computing nodes 10 with which local computing devices used by cloud consumers, such as, for example, personal digital assistant (PDA) or cellular telephone 54A, desktop computer 54B, laptop computer 54C, and/or additional computer systems may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-C shown in FIG. 2 are intended to be illustrative only and that computing nodes 10 and cloud computing environment 50 can communicate with any type of computerized device over any type of network and/or network addressable connection (e.g., using a web browser).

Referring to FIG. 2, the Program/utility 40 may include one or more program modules 42 that generally carry out the functions and/or methodologies of embodiments of the invention as described herein. Specifically, the program modules 42 may monitor real-time parking facility camera data, receive vehicle identification information for a vehicle entering a parking facility, identify driver and vehicle information based on the vehicle identification information, identify open parking spaces based on the real-time parking facility camera data, determining attributes of the open parking spaces, score the open parking spaces based on the attributes, the vehicle information, and the driver information, select a particular open parking space based on the scoring, determine navigation directions to the selected parking space, and outputting navigation directions and information for the selected parking space, e.g., to a user device of the driver and/or to a vehicle interface system, such as a vehicle navigation system. Other functionalities of the program modules 42 are described further herein such that program modules 42 are not limited to the functions described above. Moreover, it is noted that some of the modules 42 can be implemented within the infrastructure shown in FIGS. 1-3.

FIG. 4 depicts flowchart 400 depicting a method according to the present invention. The method(s) and associated process(es) are now discussed, over the course of the following paragraphs, in accordance with one embodiment of the present invention. The program(s) described herein are identified based upon the application for which they are implemented in a specific embodiment of the invention. However, it should be appreciated that any program nomenclature herein is used merely for convenience, and thus the invention should not be limited to use solely in any specific application identified and/or implied by such nomenclature.

In step 402, the Panelization Program 108, analyzes building models and architectural drawings to identify the walls of the building from all other structures and features of the building. These drawings may be architectural drawings or prints, and the models may be 2-Dimensional or 3-Dimensional models. The Panelization Program 108 is able to identify and isolate the walls from all other elements of the drawings or models. The Panelization Program 108 is able to distinguish between the various components and features of the drawings or models and the wall panels (and wall panel members) which allows the Panelization Program 108 to then calculate and generate the center lines for all of the walls and wall panels. In embodiments, where the Panelization Program 108 is provided models, the Panelization Program 108 is able to identify and isolate the wall frame structure (and the wall frame members) from the rest of the model. The Panelization Program 108 is able to work with interior and exterior.

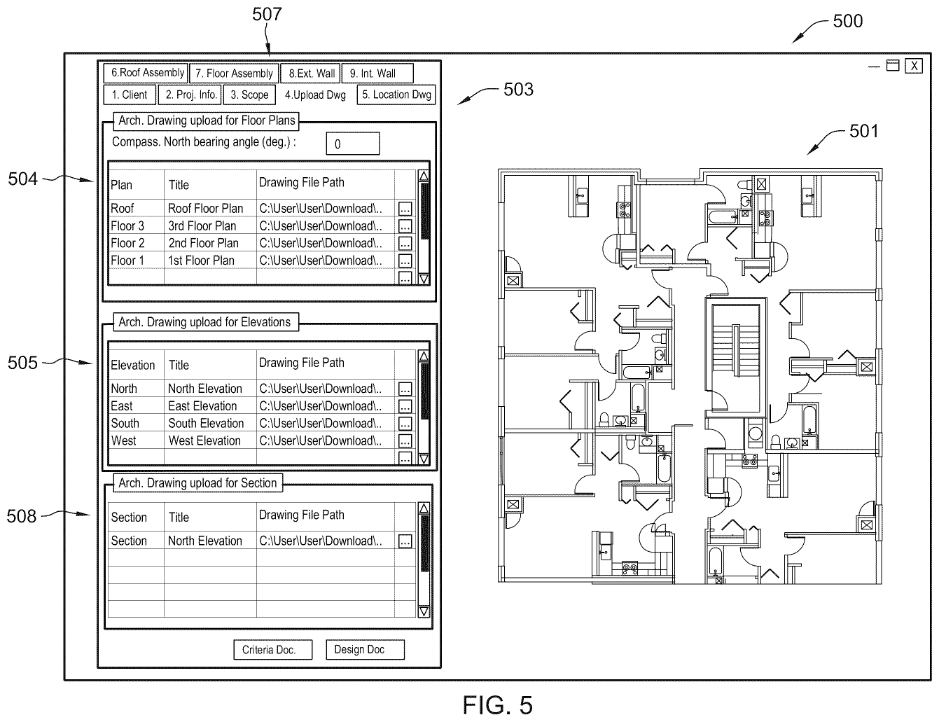

FIG. 5 depicted a user interface 500 showing an embodiment of what an architectural drawing may look like. The architectural drawing 501 has many features (e.g. doors, furniture, bathtubs, etc.) and finishing materials (e.g. drywall, windows, stairways, etc.) shown that the Panelization Program 108 is able to identify and remove these features as these are not needed, nor required for the center line calculation. In some embodiments, the walls in architectural drawings are shown with the finishing material applied and typically do not show the framing members or identify what is a wall. As shown in FIG. 5, the menu portion of the user interface 503 provides the upload ability of various files 504, 505, and 506 as well as present the various files to the user. The menus 507 are interactive and allow the user to select each menu and have access to a variety of options that allow to the user to manipulate or modify the various features of the drawing and/or model.

In some embodiments, after the analysis of the architectural drawings and the building models, Panelization Program 108 is able to take the architectural drawing and extract a drawing of just the wall, wherein the walls are isolated from the features (door swings, furniture, appliances, etc.) and text which is not necessary for the process being performed.

In step 404, the Panelization Program 108, calculates a centerline of all the identifiable walls and generates drawings and models of the center lines. In this calculation the Panelization Program 108 isolates the walls from all the other components, features, and framing of the architectural drawing or model and determines the center line of the walls. The center line is used to determine the truth width(s) of the wall frame structure. The Panelization Program 108 is able to determine based on the interface of the walls, the finishing materials of the walls, determining if the wall is an interior or exterior wall (and the structural requirements for the walls) to determine a true center of the wall.

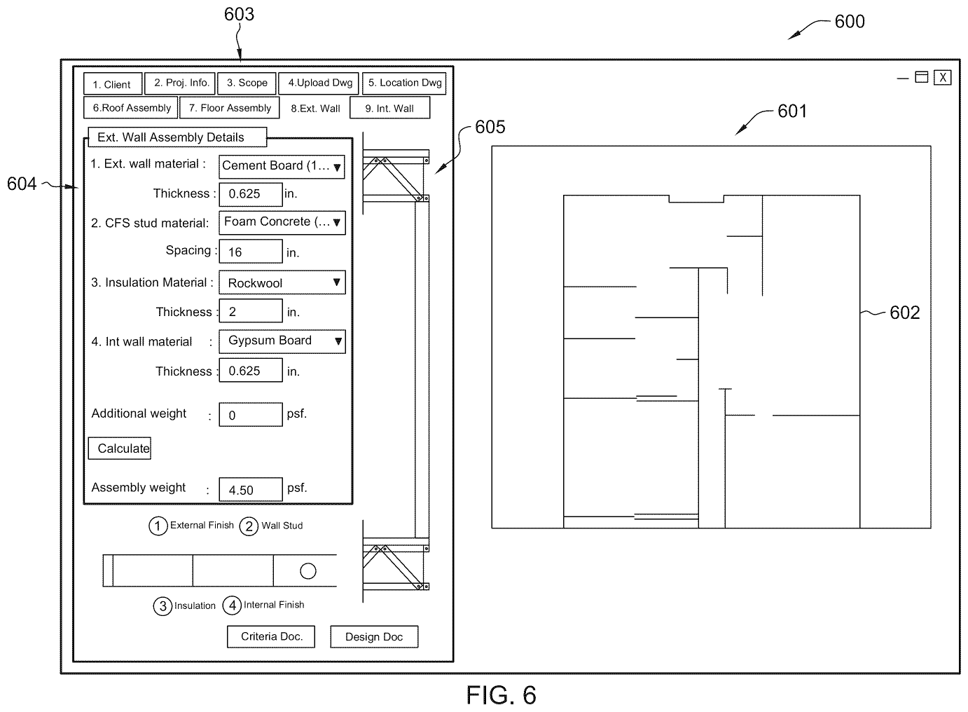

The Panelization Program 108 generates a drawing or a model of the center lines of the walls as shown in FIG. 6. The center line drawing 601 shows the center lines 602 for all of the walls within the architectural drawing or building model. This shows both the interior walls and exterior walls. This calculation is vital to determine the proper thickness of the framing materials. The user interface 600 has section 603 which provides various menus that allow the user to manipulate various details of exterior walls or interior walls which adjust the calculation to determine the center line of the wall based on these changes. As shown in menu 604, various exterior wall assembly details can be modified and adjusted as well as model 605 of wall frame and floor joists to provide an illustration of the final assembly.

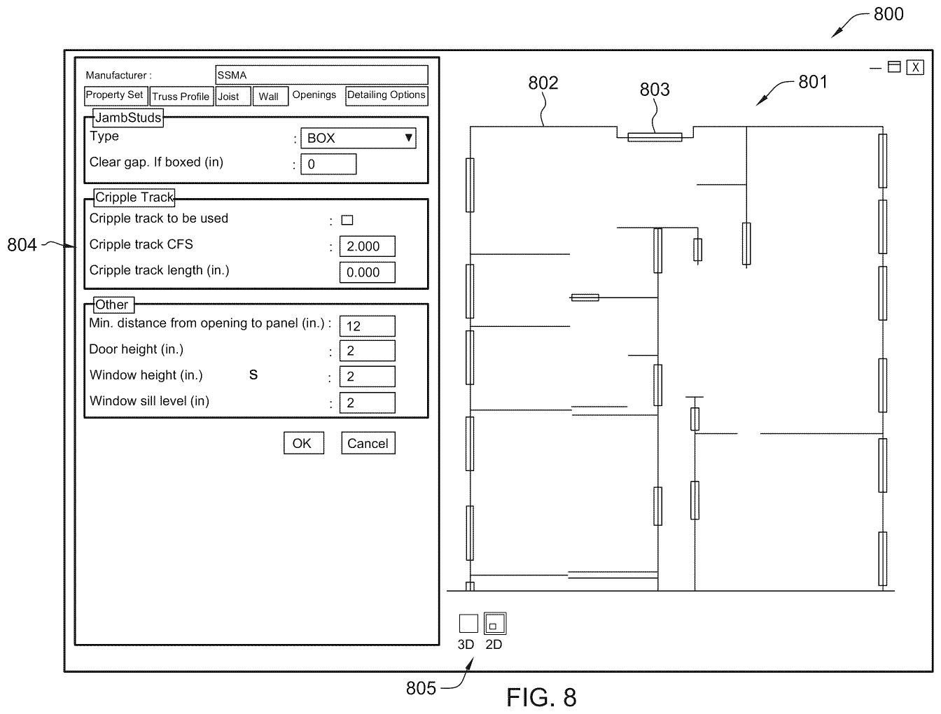

The Panelization Program 108 generates a drawing 801 of the center lines 802 of the walls (with apertures included), as shown in FIG. 8. The drawing 801 shows the apertures 803 (e.g. doors and windows, and the like). The importance of identifying the apertures assists the Panelization Program 108 to accommodate these features when calculating the true thickness of the framing members and the overall structure of the walls to accommodate these apertures 803. The user interface 800 has a series of drop down menus which the user can select. For example, the “Openings” menu has options 804 which allow for various modifications to the openings that will be applied to the drawing and/or model. Additionally, this drawing 801 allows for a 2D and a 3D view available through icons 805. The user interface 800 has a series of options 804 for the user to manipulate which are used in the overall calculation of the Panelization Program 108 to create the panels and the layers showing the centerlines and apertures.

In some embodiments, multiple drawings or models are created for each layer (or floor) of the building. This centerline drawing 600 can be overlayed with the architectural drawing to confirm the accuracy and alignment of the centerlines 601 with the original architectural drawing and determine if modifications need to be made. The Panelization Program 108 is able to analyze the overlayed drawings to determine the alignment and make additional modifications as necessary. The apertures may also be created as a separate layer as well.

In step 406, the Panelization Program 108 calculates the thickness of the framing members. Through the use of the architectural drawings (or isolated versions) or models and the centerline drawings or models, the Panelization Program 108 is able to calculate a thickness of the framing members which would be used to create the wall panels, which would be used to create the wall frame structure. The thickness of the framing members is calculated and selected based on the architectural drawings, the models, the building model design, and building requirements. Through a process of overlaying the centerline drawing with the architectural drawings and calculating the structural requirements for each of the walls a desired thickness of the framing members can be calculated. This thickness takes into account the material which the framing members are other structural requirements for each wall section/panel. This is why in some instances exterior walls or load bearing walls may have greater thickness requirements than interior walls. In some embodiments the Panelization Program 108 may increase or decrease the thickness of the wall frame members to meet or exceed building requirements and safety requirements. In some embodiments, the wall frame members are made from cold rolled steel that is created on a cold roll forming machine.

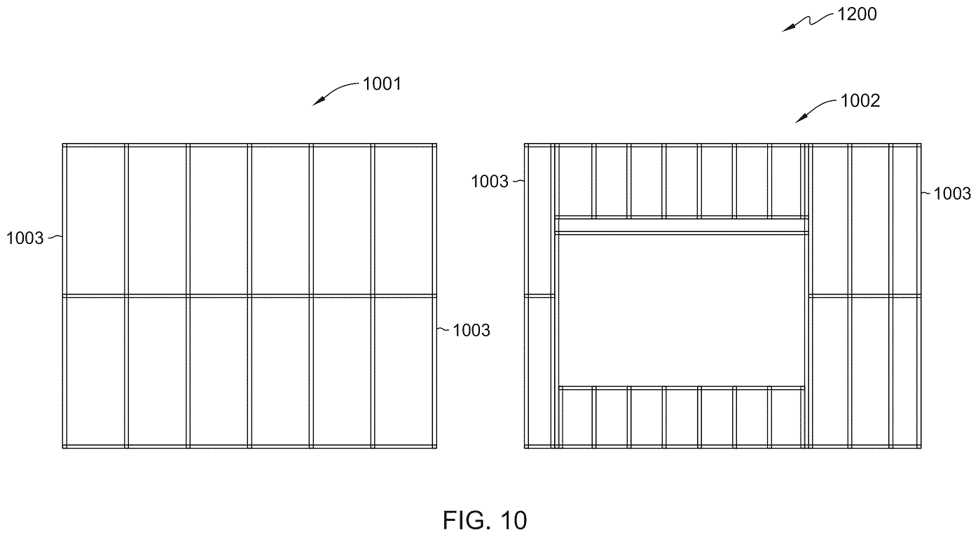

In step 408, the Panelization Program 108 creates a model of the walls which is comprised of the framing members. The Panelization Program 108 takes the thickness of the walls, the structural requirements of the walls, and the known apertures and features of the walls and creates the wall frame structure complete with all of the framing members. This includes the top plate, wall studs, fire blocks, headers, trimmer studs, king studs, bottom plate, cripple studs and the like. Using the known apertures and the wall thickness the Panelizaton Program 108 creates the models of each of the walls which include all of the framing members within the modeling software. FIG. 10 depicts wall panels 1001 and 1002, wherein each wall panel depicts all the framing members which comprise the wall panel. Panelization Program 108 is able to work with a variety of modeling software.

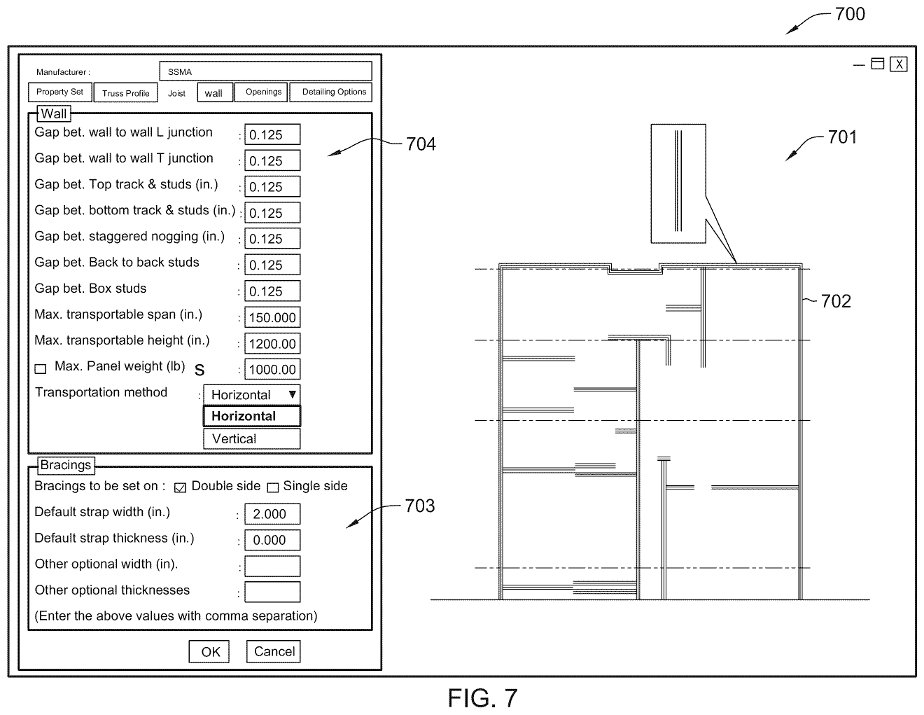

In one embodiment, the Panelization Program 108 uses the centerline information, and positioning data (from the design software) of the wall relative to a reference location or point, the relative position of wall with adjacent walls, and all other related information which can be identified by the Panelization Program 108. After the data is transferred into the design software, the wall structural width is calculated, based on the previously collected data related to the wall thickness and a drawing of the thickness of the framing members is created as shown in FIG. 7. In the depicted embodiment, true thickness drawing 701 shows the walls 702. This provides a drawing and/or a model of the true thickness of the walls 702. In some embodiments, the apertures are added into the true thickness drawing 701. Based on the number and type of layers which the features of the architectural drawings are exported into, the process may happen in parallel or in series based on the design software limitations. As shown, the user interface 700 provides multiple menus 703 and 704 that allow the user to make modifications to the walls and bracing that will be applied to the drawing 701 and will affect the overall calculation of the wall thickness.

In some embodiments, the Panelization Program 108 creates the model of the building comprised of the framing members using location information from the architectural drawings and building models, and the Panelization Program 108 is able to correctly line up each floor to create the framing member building model In some embodiments, the Panelization Program 108 is able to import other information that was preserved in various layers or data, such as details of the surfaces of the floor plan sheathing material properties, finishing material properties, insulation materials,, height of the walls, placement of various objects within the floor plan (e.g. electrical, HVAC, mechanical), and the like. This new model can be used in conjunction with other models and may become a new layering with the previously created or provided models.

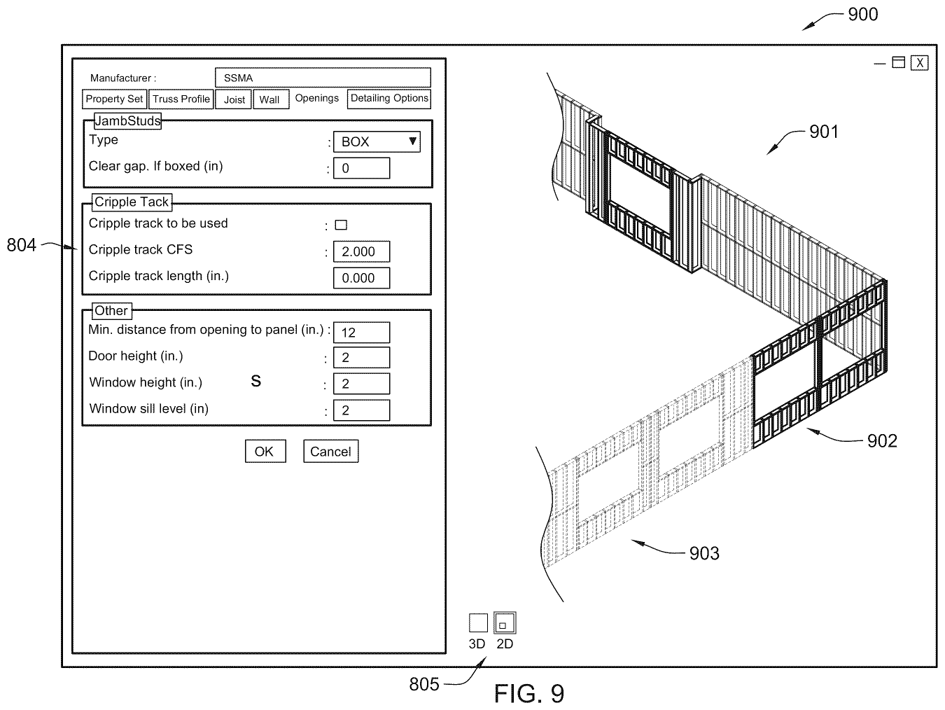

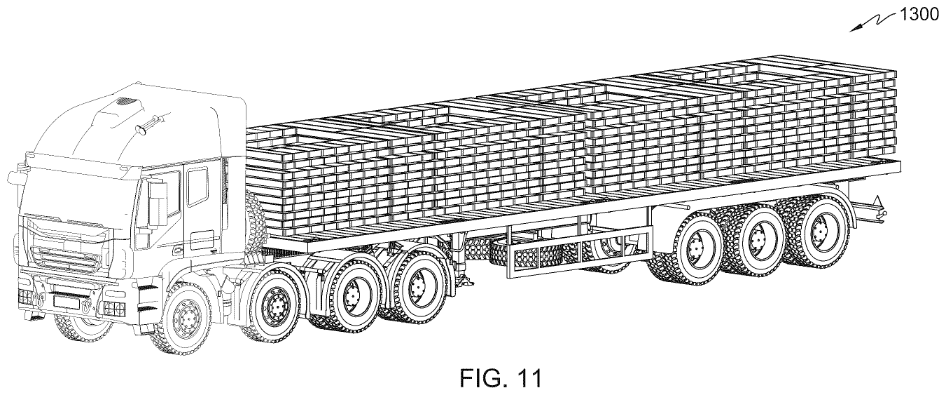

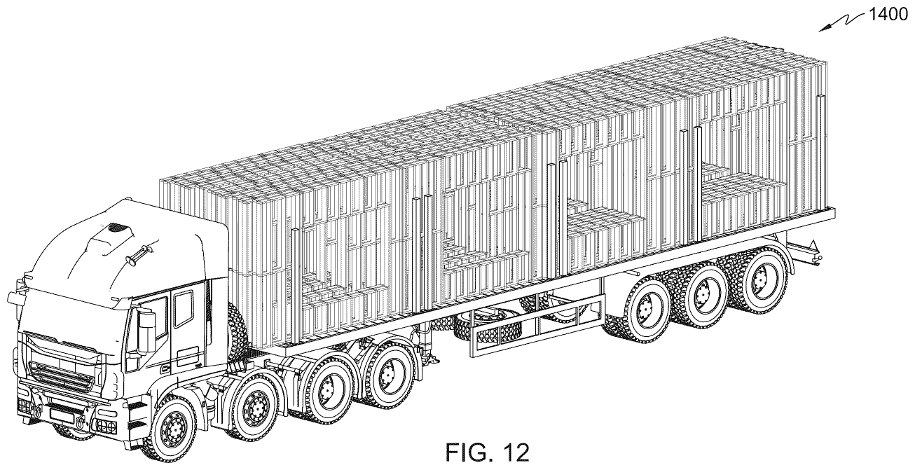

In step 410, the Panelization Program 108 analyzes the wall structure to determine the panelization of the walls to create the wall panels. The wall panels 1001 and 1002 as shown in FIG. 10 are sections of a larger wall frame structure (Shown in FIG. 9). As shown in FIG. 10, each of the wall panels 1001 and 1002 have edge framing members 1003 that typically would not be present if the entire wall was constructed in historical methods. These extra framing members if not taken into account would greatly increase the overall dimensions of the wall. Thus the Panelization Program 108 is able to manipulate the entire wall assembly to maintain the maximum dimensions, while maintaining the necessary structural integrity of the wall and create the complete wall panels. The panelization of the wall is to assist in creating either pre assembled wall panels or packets of framing members, that increase the assembly process of the building and/or assist in decreasing the transportation requirements of the walls. Through the process of creating the wall panels, each wall panel is an individual assembly, which when they are all assembled form the same structure as was created in step 408. Based on a set of limitations, such as the facility manufacturing the panels, shipping vessel restrictions (as shown in FIGS. 11 and 12), or the like the wall panels are created to a predetermined maximum size while also creating the fewest number of wall panels required to build each wall structure without losing structural integrity. FIGS. 11 and 12 depict different shipping methods of the wall panels as shown. FIG. 11 depicts a flat bed trailer with the wall panels 1300 laying flat on the trailer. FIG. 12 depicts a flat bed trailer with the wall panels 1400 standing vertically on the trailer. The shipping method is based on the calculations of the Panelization Program 108 and the size of the shipping vehicle. The Panelization Program 108 is able to, based on a set of limiters, determine how many panels need to be created to construct the wall structure. The panelization of the walls does not affect the overall dimensions of the walls.

With the creation of the multi panel walls, there is an issue that arises in terms of connecting these wall panels together. If the wall was constructed as a single panel, it would have the two end members to complete the wall panel. However, with the breaking down of the wall into multiple panels, several panels would no longer have end members and thereby create another issue with the construction of the wall. The Panelization Program 108 is able to modify the wall panels so that each wall panel has end members and is able to be secured to the adjacent wall panel(s). As shown in FIG. 9, a user interface 900 shows a 3D view of the walls 901 through the selection of icon 805. The menu 804 is shown again to allow the user to manipulate the 3D model of the walls 901. The walls 901 are divided into panels 902 and 903 (for example). The 3D model is generated in a way where each panel is visibly distinct from the other panels. The panelization of the wall provide an improvement in the overall walls strength through the additional framing members which are used. Additionally, the Panelization Program 108 is able to take into consideration the apertures within the walls, so that the wall panels which are created do not interfere or split the apertures, and the entire aperture exists within one wall panel. The drawings and data associated with each wall panel is able to be provided to a fabrication machine to create each member. For example where each member is made from cold rolled steel, the machine which fabricates these members is able to receive the wall panel data and create each member for each wall panel to size.

The Panelization Program 108 generates the manufacturing files for the roll forming machine creation. However, the generation of these manufacturing files is not advised or able to be completed until a verification of possible conflicts of the wall systems is completed. Otherwise, the potential for cold formed steel studs to be manufactured without the proper cutouts or design to accommodate the systems and either new parts need to be manufactured, or manual modification of the parts need to be completed on the job site. Both of these take time and additional resources to complete.

In step 410 the Panelization Program 108 manipulates the wall structure with the adjusted wall panels to create a panelized wall structure that shows a final assembly of the wall structure. As shown in FIG. 9, the panelized wall structure 1000 has each panel visually distinct from one another so that it is easy to delineate the separate wall panels.

The present invention provides the advantage of being able to optimize the construction of wall structures of a building by prefabricated wall panels which are then assembled at the building site, greatly reducing the construction process.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein that are believed as maybe being new, this understanding, as indicated by use of the term “present invention,” is tentative and provisional and subject to change over the course of patent prosecution as relevant information is developed and as the claims are potentially amended.

The foregoing descriptions of various embodiments have been presented only for purposes of illustration and description. They are not intended to be exhaustive or to limit the present invention to the forms disclosed. Accordingly, many modifications and variations of the present invention are possible in light of the above teachings, which will be apparent to practitioners skilled in the art. Additionally, the above disclosure is not intended to limit the present invention. In the specification and claims the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

Although various representative embodiments of this invention have been described above with a certain degree of particularity, those skilled in the art could make numerous alterations to the disclosed embodiments without departing from the spirit or scope of the inventive subject matter set forth in the specification and claims. Joinder references (e.g. attached, adhered, joined) are to be construed broadly and may include intermediate members between a connection of elements and relative movement between elements. As such, joinder references do not necessarily infer that two elements are directly connected and in fixed relation to each other. Moreover, network connection references are to be construed broadly and may include intermediate members or devices between network connections of elements. As such, network connection references do not necessarily infer that two elements are in direct communication with each other. In some instances, in methodologies directly or indirectly set forth herein, various steps and operations are described in one possible order of operation, but those skilled in the art will recognize that steps and operations may be rearranged, replaced or eliminated without necessarily departing from the spirit and scope of the present invention. It is intended that all matter contained in the above description or shown in the accompanying drawings shall be interpreted as illustrative only and not limiting. Changes in detail or structure may be made without departing from the spirit of the invention as defined in the appended claims.

Although the present invention has been described with reference to the embodiments outlined above, various alternatives, modifications, variations, improvements and/or substantial equivalents, whether known or that are or may be presently foreseen, may become apparent to those having at least ordinary skill in the art. Listing the steps of a method in a certain order does not constitute any limitation on the order of the steps of the method. Accordingly, the embodiments of the invention set forth above are intended to be illustrative, not limiting. Persons skilled in the art will recognize that changes may be made in form and detail without departing from the spirit and scope of the invention. Therefore, the invention is intended to embrace all known or earlier developed alternatives, modifications, variations, improvements and/or substantial equivalents.

What is claimed is:

1. A computer method for creating wall panels of a building structure, comprising:
receiving, by one or more processors, architectural drawings of a building;
isolating, by the one or more processors, a series of walls from the architectural drawings;
calculating, by the one or more processors, a centerline of each segment of the series of the walls;
generating, by the one or more processors, a drawing of the centerlines;
calculating, by the one or more processors, a thickness of each of the segments of the series of the walls based on the architectural drawings and the centerline drawing;
creating, by the one or more processors, a model of the segments of the series of the walls, wherein each segment is comprised of a set of framing members;
analyzing, by the one or more processors, the segments of the series of the walls wherein wall panels are formed;
manipulating, by the one or more processors, the segments of the series of the walls based on the analyzed wall panels; and
generating, by the one or more processors, a model of the each of the wall panels and a model of the building assembly.

2. The computer method for creating wall panels of a building structure of claim 1, further comprising, differentiating, by the one or more processors, interior walls from exterior walls.

3. The computer method for creating wall panels of a building structure of claim 1, further comprising, identifying, by the one or more processors, apertures within the series of walls.

4. The computer method for creating wall panels of a building structure of claim 3, further comprising, overlaying, by the one or more processors, the apertures within the series of walls on the drawing of the centerlines.

5. The computer method for creating wall panels of a building structure of claim 1, further comprising, manipulating, by the one or more processors, the segments of the series of the walls so that each segment is visibly distinct from any adjacent segments.

6. The computer method for creating wall panels of a building structure of claim 1, wherein, the analyzing of the segments of the series of the walls wherein wall panels are formed, further comprising, applying, by the one or more processors, edge framing members where the wall panel does not have an edge framing member.

7. The computer method for creating wall panels of a building structure of claim 1, wherein a set of wall assembly properties are selected and incorporated into the analyses of the segments of the series of the walls wherein wall panels are formed.

8. A computer program product for creating wall panels of a building structure:
the computer program product comprising a computer readable storage medium having program instructions embodied therewith, the program instructions executable by a computing device to cause the computing device to:
program instructions to receive architectural drawings of a building, wherein the architectural drawings of the building have multiple floors;
program instructions to analyze each of the architectural drawings to identify walls from other components of the architectural drawings and isolating the walls from the other components of the architectural drawings;
program instructions to calculate a centerline of each the walls;
program instructions to generate a drawing of the centerlines that align with the walls of the architectural drawings;
program instructions to calculate a true thickness of each of the walls based on a framing member measurements;
program instructions to create a model of the walls, wherein the walls are constructed from the framing member, and wherein the wall is constructed to a building design;
program instructions to analyze the walls, and wherein the wall is segmented into a series of wall panels;
program instructions to manipulate the segments of the series of wall panels; and
program instructions to generate a model of the each of the wall panels and a model of the building assembly.

9. The computer program product for creating wall panels of a building structure of claim 8, further comprising, program instructions to differentiate interior walls from exterior walls.

10. The computer program product for creating wall panels of a building structure of claim 8, further comprising, program instructions to identify apertures within the walls.

11. The computer program product for creating wall panels of a building structure of claim 10, further comprising, program instructions to overlay the apertures on the drawing of the centerlines.

12. The computer program product for creating wall panels of a building structure of claim 8, further comprising, program instructions to manipulate the segments of the series of wall panels so that each segment is visibly distinct from adjacent segments.

13. The computer program product for creating wall panels of a building structure of claim 8, further comprising, generating a set of files of each of the framing members and each of the segments of the wall panels which are readable by a roll forming machine.

14. The computer program product for creating wall panels of a building structure of claim 8, wherein a set of wall assembly properties are selected and the walls and the series of wall panels are manipulated based on the selected properties.

15. A system comprising:
a CPU, a computer readable memory and a computer readable storage medium associated with a computing device;
program instructions to receive architectural drawings;
program instructions to analyze each of the architectural drawings to identify structural features of the architectural drawings and isolating the structural features associated with the walls;
program instructions to calculate a centerline of each the walls;
program instructions to generate a drawing of the centerlines which aligns with the architectural drawings;
program instructions to calculate a true thickness of each of the walls based on a framing member setoff properties;
program instructions to create a model of the walls, wherein the walls are constructed from framing members, and wherein the wall is constructed based on a set of building requirements;
program instructions to analyze the walls, and wherein the wall is segmented into a series of wall panels;
program instructions to manipulate the segments of the series of wall panels and adjust the walls to accommodate these manipulations; and
program instructions to generate a model of the each of the wall panels and a model of the building assembly.

16. The system of claim 15, wherein the centerline calculation removes unnecessary features of the walls within the architectural drawings.

17. The system of claim 15, further comprising, program instructions to make each wall panel visually distinct from adjacent wall panels.

18. The system of claim 15, further comprising, identifying features of the walls, and incorporating these features into the creation of the model of the walls.

19. The system of claim 18, wherein the identified features are incorporated into the processing of the construction of the wall based on the set of building requirements.

20. The system of claim 15, further comprising, comparing the wall panels to a set of shipping restrictions and creating a bundle of the wall panels for shipping.
